(19) United States
(12) Patent Application Publication
(10) Pub. No.: US 2016/0380081 A1
(43) Pub. Date: Dec. 29, 2016

(54) FINFET AND METHOD OF FABRICATING THE SAME

(71) Applicant: United Microelectronics Corp., Hsin-Chu City (TW)

(72) Inventors: Chih-Kai Hsu, Tainan City (TW); Yu-Hsiang Hung, Tainan City (TW); Ssu-I Fu, Kaohsiung City (TW); Jyh-Shyang Jenq, Pingtung County (TW)

(21) Appl. No.: 14/818,322

(22) Filed: Aug. 5, 2015

(30) Foreign Application Priority Data
Jun. 25, 2015 (CN) 201510355085.X

(51) Int. Cl. H01L 29/66; H01L 29/78; H01L 21/762

(52) U.S. Cl. CPC H01L 29/66795; H01L 21/76224; H01L 29/7851

(57) ABSTRACT

A FinFET includes a substrate. Numerous fin structures are defined on the substrate. A gate structure crosses each fin structure. Two epitaxial layers are disposed at two side of the gate structure, respectively. Each epitaxial layer has a top surface including a second recessed and protruding profile. A contact plug contacts the second recessed and protruding profile. The second recessed and protruding profile increases the contact area between the contact plug and the epitaxial layer.

### BACKGROUND OF THE INVENTION

1. Field of the Invention

The present invention relates to a FinFET (fin-shaped field-effect transistor), and more particularly to a FinFET having an epitaxial layer comprising a recessed and protruding profile, and a method of making the same.

2. Description of the Prior Art

In the rapidly advancing semiconductor manufacturing industry, FinFET devices are increasingly used in many applications and are integrated into various different types of semiconductor devices. The use of fins increases the surface areas of the channel and source/drain regions. This increased surface area results in faster, more reliable and better-controlled semiconductor transistor devices that consume less power.

As the size of the FinFET becomes smaller, however, the epitaxial layer serving as the source/drain region also shrinks. Therefore, the contact area between the contact plug and the epitaxial layer becomes smaller, which increases the sheet resistance of the contact plug.

### SUMMARY OF THE INVENTION

It is an objective of the present invention to provide a novel method of fabricating a FinFET wherein the contact plug has a low sheet resistance.

According to a preferred embodiment of the present invention, a method of fabricating a FinFET includes providing a substrate having a plurality of fin structures disposed thereon, an STI disposed between adjacent fin structures and a gate structure crossing the fin structures. Later, the fin structures not covered by the gate structure and the STI not covered by the gate structure are etched until the STI is removed entirely and a first recessed and protruding profile is formed on the substrate. Finally, an epitaxial layer is formed on the first recessed and protruding profile, wherein the epitaxial layer comprises a top surface, and the top surface comprises a second recessed and protruding profile.

According to another preferred embodiment of the present invention, a FinFET, includes a substrate having a plurality of fin structures defined thereon, a gate structure crossing the fin structures and two epitaxial layers disposed at two side of the gate structure, wherein a top surface of each epitaxial layer comprises a second recessed and protruding profile.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 9 depict a method of fabricating a FinFET according to a preferred embodiment of the present invention, wherein:

FIG. 2 is a sectional view taken along line AA′ in FIG. 1;

FIG. 4 is a sectional view taken along line BB′ in FIG. 3;

FIG. 6 is a sectional view taken along line CC′ in FIG. 5; and

FIG. 8 is a sectional view taken along line DD′ in FIG. 7.

FIG. 10 shows a layout of a FinFET.

### DETAILED DESCRIPTION

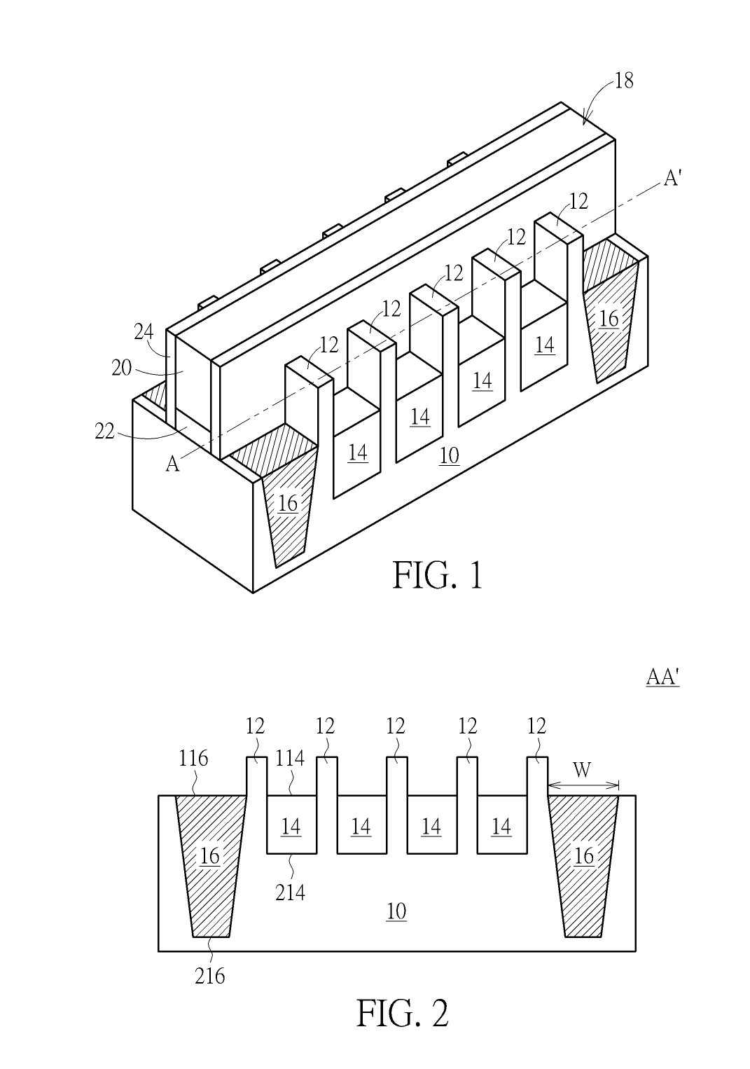

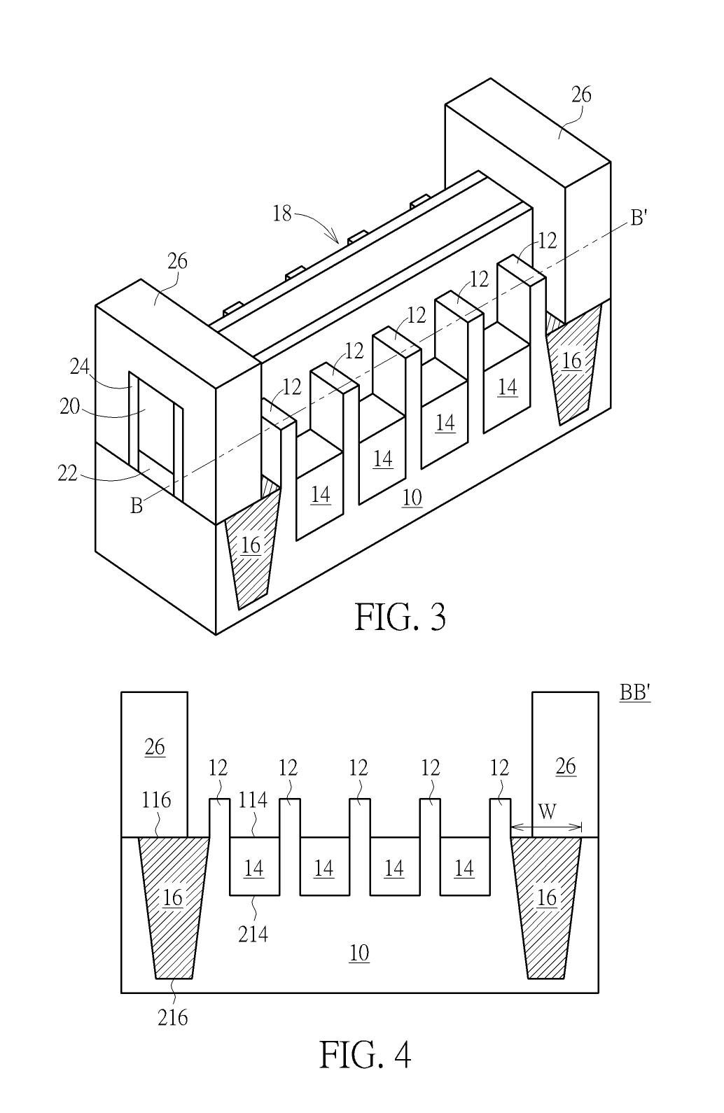

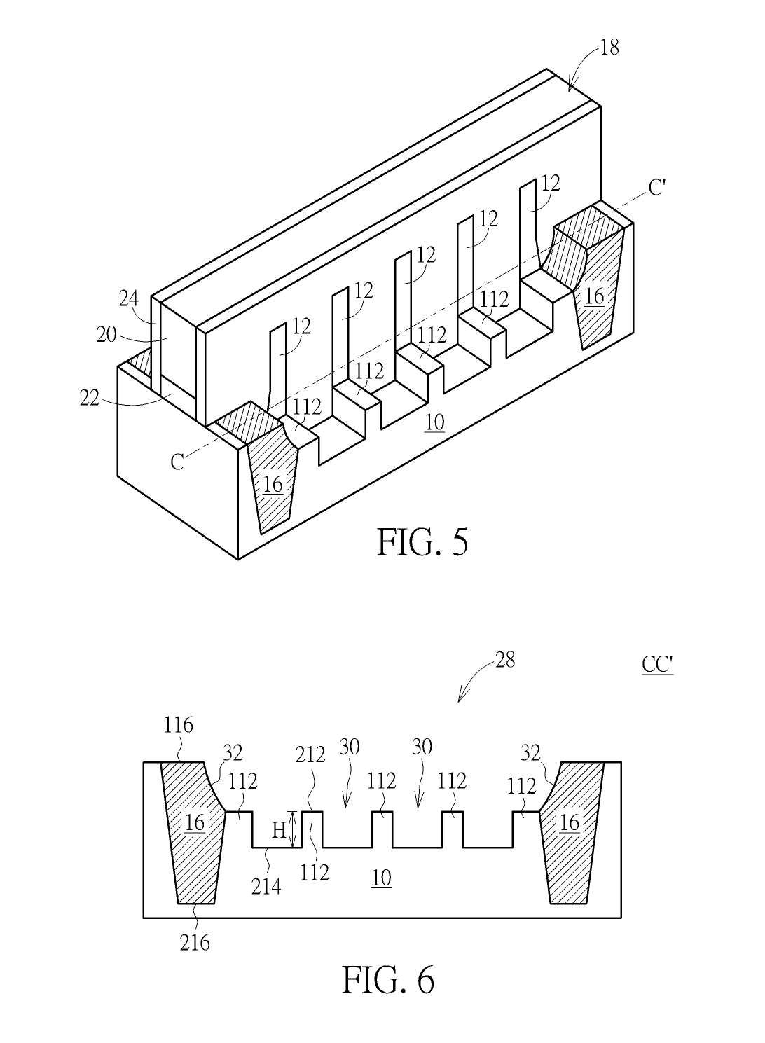

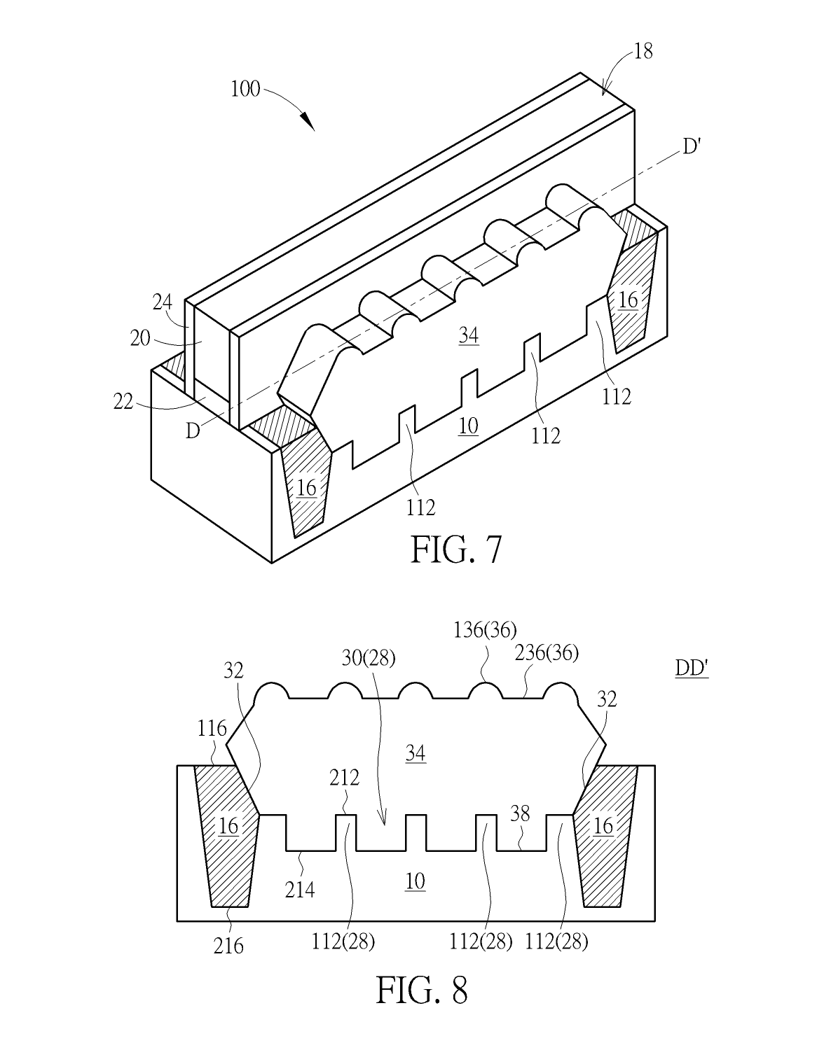

FIG. 1 to FIG. 9 depict a method of fabricating a FinFET according to a preferred embodiment of present invention, wherein FIG. 2 is a sectional view taken along line AA′ in FIG. 1, FIG. 4 is a sectional view taken along line BB′ in FIG. 3, FIG. 6 is a sectional view taken along line CC′ in FIG. 5 and FIG. 8 is a sectional view taken along line DD′ in FIG. 7.

As shown in FIG. 1 and FIG. 2, a substrate 10 is provided. The substrate 10 has numerous fin structures 12 defined thereon. In other words, the fin structures 12 are formed by removing part of the substrate 10, so that the fin structure becomes part of the substrate 10. The number of the fin structures is not limited. In addition, the fin structures 12 are parallel to one another. A shallow trench isolation (STI) 14 is disposed between two adjacent fin structures 12. The STI 14 is on the substrate 10. A deep trench isolation (DTI) is disposed within the substrate, wherein the DTI 16 is disposed at a side of the fin structure 12 which is the first or the last among all of the fin structures 12. A top surface 116 of the DTI 16 is aligned with a top surface 114 of the STI 14. The A bottom 216 of the DTI 16 is deeper than a bottom 114 of the STI 14. Moreover, agate structure 18 crosses each fin structure 12, the DTI 16 and the STI 14. The gate structure 18 may include a gate electrode 20 and a gate dielectric layer 22. The gate structure 18 can optionally comprise a spacer 24. The gate dielectric layer 22 contacts the fin structures 12, the DTI 16 and the STI 14. The gate electrode 20 is disposed on the gate dielectric layer 22, and the spacer 24 is disposed at two sides of the gate electrode 20.

As shown in FIG. 3 and FIG. 4, a mask layer 26 is formed to cover the gate structure 18, and at least part of the DTI 16. The fin structures 12 at two sides of the gate structure 18, the STI 14 and part of the DTI 16 are exposed through an opening of the mask layer 26. As shown in FIG. 4, the DTI 16 includes a surface width W. At least one quarter of the surface width W to one half of the surface width W should be exposed through the opening of the mask layer 26. In FIG. 3, in order to show the relative position of each element, the mask layer 26 only covers part of the gate structure 18. In the real process, the mask layer 26 should cover the entire gate structure 18.

As shown in FIG. 5 and FIG. 6, the exposed fin structures 12, the exposed STI 14 and the exposed DTI 16 are removed to form a first recessed and protruding profile 28 on the substrate 10. Later, the mask layer 26 is removed. The first recessed and protruding profile 28 is teeth-like. In detail, the fin structures 12, the exposed STI 14 and the exposed DTI 16 can be removed by an etching process. The etching process is preferably a dry etching process. For example, initially, a first etching condition which has a high etching ratio of silicon in comparison with the silicon oxide is applied. Because the STI 14 is made of silicon oxide and the fin structures 12 is made of a silicon substrate, the fin structures 12 are etched while the STI 14 is not etched during the first etching condition. Then, a second etching condition which has an etching ratio of silicon to silicon oxide of 1:1 is applied. The fin structure 12 and the STI 14 are etched simultaneously until the STI 14 is removed entirely. In other words, the STI 14 at two sides of the gate structure 18 and not covered by the gate structure 18 is entirely etched. Furthermore, the fin structures 12 at two sides of the gate structure 18 and not covered by the gate structure 18 are also etched while etching the STI 14. The etched fin structures 12 form numerous shortened fin structures 112. The numerous shortened fin structures 112 constitute the protruding portions of the first recessed and protruding profile 28. After the STI 14 is entirely removed, the substrate 10 originally covered by the STI 14 forms a recess 30, so that adjacent shortened fin structures 112 define the recess 30. The recess 30 constitutes the recessed portions of the first recessed and protruding profile 28. When etching the exposed STI 14 and the exposed fin structures 12, part of the DTI 16 is removed as well. Therefore, a recess 32 is formed on the remaining DTI 16. The recess 32 is adjacent to one of the shortened fin structures 112, and the recess 32 forms a continuous profile with the top surface 212 of the shortened fin structure 112. According to a preferred embodiment of the present invention, a height H of each shortened fin structure 112 is 100 to 200 nm, and the top surface 212 of the shortened fin structure 112 is lower than the top surface 116 of the DTI 16. In addition, each of the shortened fin structures 112 extends from the corresponding fin structure 12.

As shown in FIG. 7 and FIG. 8, an epitaxial layer 34 is formed on the first recessed and protruding profile 28. The epitaxial layer 34 comprises a top surface, and the top surface has a second recessed and protruding profile 36. The epitaxial layer 34 contacts the first recessed and protruding profile 28, the DTI 16 and the recess 32 on the DTI 16. Since the first recessed and protruding profile 28 is made of silicon, the epitaxial layer 34 can be formed by an epitaxial growth process using the first recessed and protruding profile 28 as a seed layer. Therefore, the shape of the second recessed and protruding profile 36 is influenced by the first recessed and protruding profile 28. In detail, the shortened fin structure 112 corresponds to a protruding portion 136 of the second recessed and protruding profile 36. The recess 30 corresponds to a recessed portion 236 of the second recessed and protruding profile 36. After the epitaxial growth process, the shortened fin structures 112 cause the protruding portion 136 of the second recessed and protruding profile 36, and the recess 30 causes the recessed portion 236 of the second recessed and protruding profile 36. Therefore, the number of the shortened fin structures 112 matches the number of the protruding portion 136. In addition, a bottom of the epitaxial layer 34 includes a third recessed and protruding profile 38. The third recessed and protruding profile 38 is complementary to the first recessed and protruding profile 28 to make the third recessed and protruding profile 38 engage into the first recessed and protruding profile 28. At this point, a FinFET of the present invention is completed. In the etching process described in FIG. 5 and FIG. 6, part of the DTI 16 is removed and the recess 32 is formed on the DTI 16. Therefore, when the epitaxial layer is growing, the epitaxial layer 34 can grow laterally along the lattice direction to extend into the recess 32. In this way, the growth of the epitaxial layer 34 will not be blocked by the DTI 16, and the lattice of the epitaxial layer 34 can be formed completely.

As shown in FIG. 8, a contact plug 40 is formed on the epitaxial layer 34. The contact plug 40 contacts and electrically connects to the epitaxial layer 34. In addition, before the contact plug 40 is formed, a silicide layer (not shown) can be formed on the top surface of the epitaxial layer 34.

FIG. 7 is a three dimensional diagram depicting a FinFET of the present invention. FIG. 8 is a sectional view taken along line DD′ in FIG. 7. FIG. 10 shows a layout of a FinFET, wherein FIG. 7 shows the sectional view of the framed part in FIG. 10.

Please refer to FIG. 1, FIG. 7, FIG. 8 and FIG. 10. A FinFET includes a substrate 10. The substrate 10 maybe a silicon substrate. Numerous fin structures 12 are defined on the substrate 10. A gate structure 18 covers and crosses each fin structure 12. Two epitaxial layers 34 are disposed at two sides of the gate structure 18. Each epitaxial layer 34 includes a top surface. The top surface has a second recessed and protruding profile 36. The fin structure 12 is covered by the gate structure 18 and blocked by the epitaxial layers 34. FIG. 1 details the relative positions of the fin structure 12 and the gate structure 18. The gate structure 18 includes a gate electrode 20 and a gate dielectric layer 22. The gate structure 18 can optionally include a spacer 34 surrounding the gate structure 18. Please refer to FIG. 7, FIG. 8 and FIG. 10. Two DTIs 16 are disposed within the substrate 10. Each DTI 16 is at two ends of each epitaxial layer 34, and the epitaxial layers 34 contact the DTIs 16. Moreover, the gate structure 18 also covers the DTIs. A recess 32 is on each of the DTIs 16. Each epitaxial layer 34 fills in the corresponding recess 32.

As shown in FIG. 7, numerous shortened fin structures 112 are defined on the substrate 10 at two sides of the gate structure 18. As shown in FIG. 5, each shortened fin structure 112 extends from the corresponding fin structure 12. A height of each shortened fin structure 112 is smaller than a height of each fin structure 12. Moreover, the shortened fin structures 112 are parallel to one another. Please refer to FIG. 7 and FIG. 8. A recess 30 is formed between two adjacent shortened fin structures 112. In addition, the substrate 10 has a first recessed and protruding profile 28. The numerous shortened fin structures 112 constitute the protruding portions of the first recessed and protruding profile 28. The recess 30 constitutes the recessed portions of the first recessed and protruding profile 28. A bottom of the epitaxial layer 34 includes a third recessed and protruding profile 38. The third recessed and protruding profile 38 is complementary to the first recessed and protruding profile 28 to make the third recessed and protruding profile 38 engage into the first recessed and protruding profile 28.

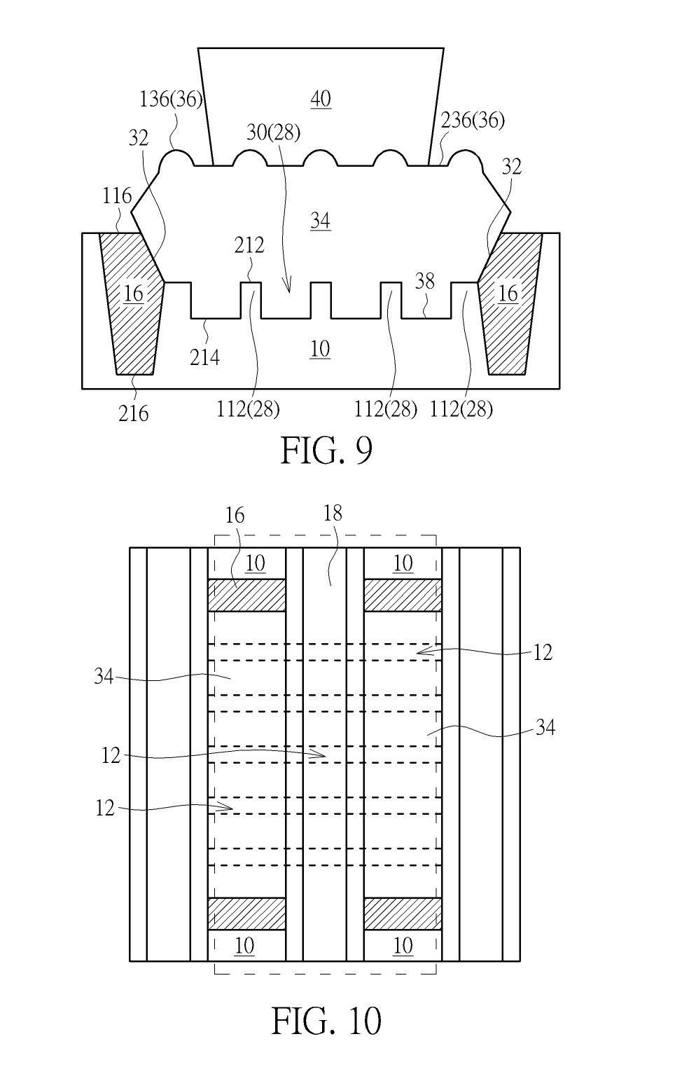

The shortened fin structure 112 corresponds to a protruding portion 136 of the second recessed and protruding profile 36. The recess 30 corresponds to a recessed portion 236 of the second recessed and protruding profile 36. In other words, after the epitaxial growth process, the shortened fin structures 112 cause the protruding portion 136 of the second recessed and protruding profile 36, and the recess 30 causes the recessed portion 236 of the second recessed and protruding profile 36. Therefore, the number of the shortened fin structures 112 matches the number of the protruding portion 136. As a result, the second recessed and protruding profile 36 becomes an uneven continuous surface. According to a preferred embodiment of the present invention, the second recessed and protruding profile 36 can be wave-like. As shown in FIG. 9, a contact plug 40 can be disposed on at least one of the epitaxial layers 34 to contact the second recessed and protruding profile 36. The interface between the contact plug 40 and the second recessed and protruding profile 36 is also a recessed and protruding profile.

As shown in FIG. 9 and FIG. 10, each of the epitaxial layers 34 includes the second recessed and protruding profile 36 to increase the contact area. As the contact area increases, the sheet resistance of the contact plug 40 decreases. In a conventional FinFET, each fin has its own epitaxial layers disposed at two sides of the gate structure, and the epitaxial layer on one fin structure does not contact the epitaxial layers on the other fin structure, so there are numerous epitaxial layers at the same side of the gate structure. The epitaxial layers at the same side of the gate structure are connected to the same circuit. In the present invention, however, all fin structures share one bulk epitaxial layer 34 at the same side of the gate structure 18. The bulk epitaxial layer 34 will have smaller resistance compared to the conventional epitaxial layers.

As shown in FIG. 8 and FIG. 10, DTIs 16 are disposed at two ends of each epitaxial layer 34. A bottom of the DTI 16 is deeper than a bottom of the epitaxial layer 34. Therefore, the DTI 16 can isolate the epitaxial layer 34 from the epitaxial layer 34 belonging to an adjacent FinFET.

Those skilled in the art will readily observe that numerous modifications and alterations of the device and method may be made while retaining the teachings of the invention. Accordingly, the above disclosure should be construed as limited only by the metes and bounds of the appended claims.

1. A method of fabricating a FinFET, comprising:
providing a substrate having a plurality of fin structures disposed thereon, an STI disposed between adjacent fin structures and a gate structure crossing the fin structures;
etching the fin structures not covered by the gate structure to form a plurality of shortened fin structures extending from the fin structures and disposed at two sides of the gate structure and etching the STI not covered by the gate structure until the STI is removed entirely and a first recessed and protruding profile is formed on the substrate; and
forming an epitaxial layer on the first recessed and protruding profile, wherein the epitaxial layer comprises a top surface, the top surface comprises a second recessed and protruding profile and the epitaxial layer contacts each of the shortened fin structures.

2. The method of fabricating a FinFET of claim 1, further comprising a DTI disposed within the substrate, wherein the DTI is disposed at a side of the fin structure being the first or the last among all of the fin structures, and a bottom of the DTI is deeper than a bottom of the STI.

3. The method of fabricating a FinFET of claim 2, further comprising:
before etching the fin structures and the STI, forming a mask layer covering the gate structure and part of the DTI to expose the fin structures disposed at two sides of the gate structure, and to expose the STI and at least part of the DTI.

4. The method of fabricating a FinFET of claim 3, further comprising:
when etching the fin structures and the STI, also etching the exposed DTI.

5. The method of fabricating a FinFET of claim 1, wherein each of the shortened fin structures constitutes a protruding portion of the first recessed and protruding profile, and after the STI is removed entirely, the substrate originally covered by the STI forms a recess, the recess constituting a recessed portion of the first recessed and protruding profile.

6. The method of fabricating a FinFET of claim 5, wherein each of the shortened fin structures corresponds to a protruding portion of the second recessed and protruding profile, and the recess corresponds to a recessed portion of the second recessed and protruding profile.

7. The method of fabricating a FinFET of claim 1, further comprising:
after forming the epitaxial layer, forming a contact plug contacting the second recessed and protruding profile of the epitaxial layer.

8. A FinFET, comprising:
a substrate having a plurality of fin structures defined thereon;
a gate structure crossing the fin structures;
a plurality of shortened fin structures extend from the fin structures and disposed at two sides of the gate structure; and
two epitaxial layers disposed at two side of the gate structure, wherein a top surface of each epitaxial layer comprises a second recessed and protruding profile and each of the epitaxial layers contacts each of the shortened fin structures.

9. The FinFET of claim 8, further comprising a contact plug contacting at least one of the second recessed and protruding profile of the epitaxial layers.

10. The FinFET of claim 8, further comprising two DTIs disposed within the substrate, wherein the DTIs are respectively disposed at two ends of each epitaxial layer, and the epitaxial layer contacts the DTI.

11. The FinFET of claim 8, wherein a height of each shortened fin structure is smaller than a height of each fin structure.

12. The FinFET of claim 8, wherein a recess is formed between two adjacent shortened fin structures.

13. The FinFET of claim 12, wherein the substrate comprises a first recessed and protruding profile, each of the shortened fin structures constitutes a protruding portion of the first recessed and protruding profile, and the recess constitutes a recessed portion of the first recessed and protruding profile.

14. The FinFET of claim 13, wherein each epitaxial layer comprises a third recessed and protruding profile, and the third recessed and protruding profile is complementary to the first recessed and protruding profile to make the third recessed and protruding profile engage with the first recessed and protruding profile.

15. The FinFET of claim 13, wherein the shortened fin structures are parallel to one another.

16. A FinFET, comprising:
a substrate having a plurality of fin structures defined thereon;
a gate structure crossing the fin structures;
a plurality of shortened fin structures extend from the fin structures and disposed at two sides of the gate structure;
a recess defined between the shortened fin structures; and
two epitaxial layers disposed at two side of the gate structure, in the recess and contacting the recess, wherein a top surface of each epitaxial layer comprises a second recessed and protruding profile.
